(19) United States
(12) Patent Application Publication
(10) Pub. No.: US 2014/0116878 A1
(43) Pub. Date: May 1, 2014

(54) APPARATUS AND METHOD FOR SPUTTERING A TARGET USING A MAGNET UNIT

(71) Applicant: ACE TECHNOLOGIES CORPORATION, Incheon (KR)

(72) Inventors: Myoung-Ho Kim, Incheon (KR); Myung-Joon Jung, Bucheon (KR)

(21) Appl. No.: 14/044,397

(22) Filed: Oct. 2, 2013

(30) Foreign Application Priority Data
Oct. 26, 2012 (KR) 10-2012-0119885

(51) Int. Cl. C23C 14/35

(52) U.S. Cl. CPC C23C 14/35
USPC 204/298.16

(57) ABSTRACT

A sputtering apparatus and method are disclosed which can reduce deviations in the deposition thickness on the target object. The sputtering apparatus may include a chamber body and a targeting module. The targeting module may be positioned inside the chamber body and may include a source and at least one magnet unit, where the magnet unit may be configured to generate a magnetic field. Here, the magnet unit can be made to swing during a sputtering process.

### CROSS-REFERENCE TO RELATED APPLICATIONS

This application claims the benefit of Korean Patent Application No. 10-2012-0119885, filed with the Korean Intellectual Property Office on Oct. 26, 2012, the disclosure of which is incorporated herein by reference in its entirety.

### TECHNICAL BACKGROUND

The present invention relates to an apparatus and method for sputtering a target by using a magnet unit.

### RELATED ART

A sputtering apparatus refers to an apparatus that applies sputtering on a target for a depositing process. There are numerous types of sputtering apparatuses available, an example of which is disclosed in Korean Patent Publication No. 2012-39856, but in many cases, the lifespan of the deposited material is short, and there are severe deviations in deposition thickness on the target object.

### SUMMARY

An aspect of the invention is to provide a sputtering apparatus and method that can reduce deviations in deposition thickness on the target object.

To achieve the objective above, an embodiment of the invention provides a sputtering apparatus that includes a chamber body and a targeting module. The targeting module is positioned inside the chamber body and includes a source and at least one magnet unit, where the magnet unit is configured to generate a magnetic field. Here, the magnet unit swings during a sputtering process.

Another embodiment of the invention provides a targeting module used in a sputtering apparatus, where the targeting module includes a source and a magnet part that has at least one magnet unit configured to generate a magnetic field. Here, the magnet part is capable of swinging.

Yet another embodiment of the invention provides a sputtering process that includes: generating ions; concentrating the ions by generating a magnetic field; and sputtering a source with the ions. Here, the output direction of the magnetic field is changed once or more during the sputtering.

A sputtering apparatus and method based on certain embodiments of the present invention may involve rotating the source and swinging the magnet unit, and thus can lengthen the lifespan of the source and reduce the deposition thickness on the target object.

Additional aspects and advantages of the present invention will be set forth in part in the description which follows, and in part will be obvious from the description, or may be learned by practice of the invention.

### BRIEF DESCRIPTION OF THE DRAWINGS

FIG. 1A and FIG. 1B are cross-sectional views schematically illustrating a sputtering apparatus according to a first disclosed embodiment of the invention.

FIG. 2A and FIG. 2B are diagrams illustrating the operation of a targeting module according to an embodiment of the invention.

FIG. 3 is a cross-sectional view schematically illustrating a sputtering apparatus according to a second disclosed embodiment of the invention.

FIG. 4 is a cross-sectional view schematically illustrating a sputtering apparatus according to a third disclosed embodiment of the invention.

### DETAILED DESCRIPTION

As the present invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In describing the drawings, like reference numerals are used for like elements.

Certain embodiments of the invention will be described below in more detail with reference to the accompanying drawings.

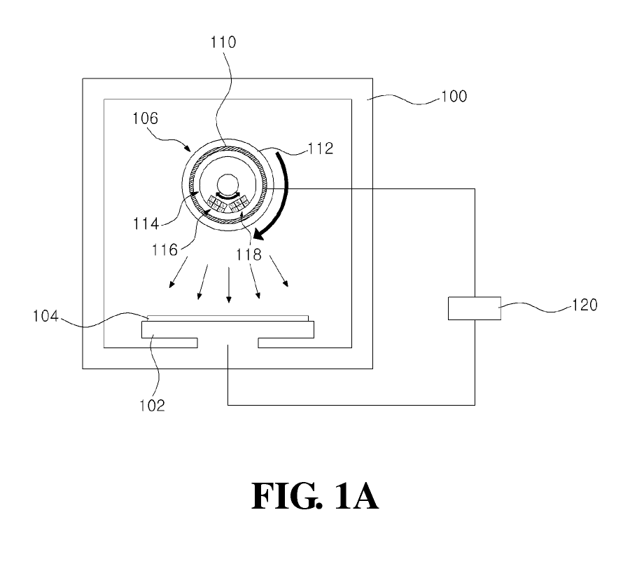

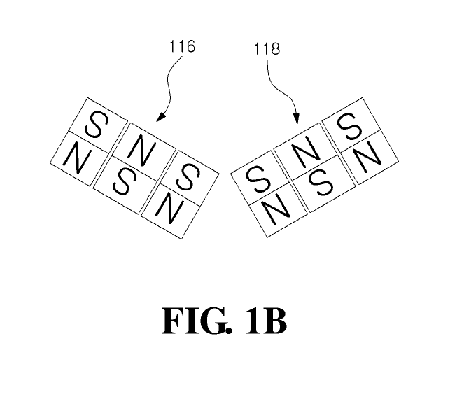

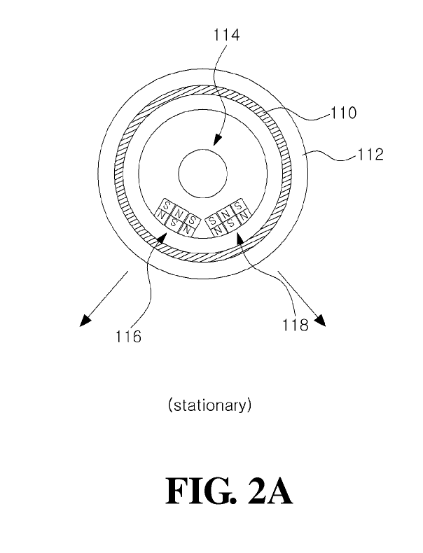

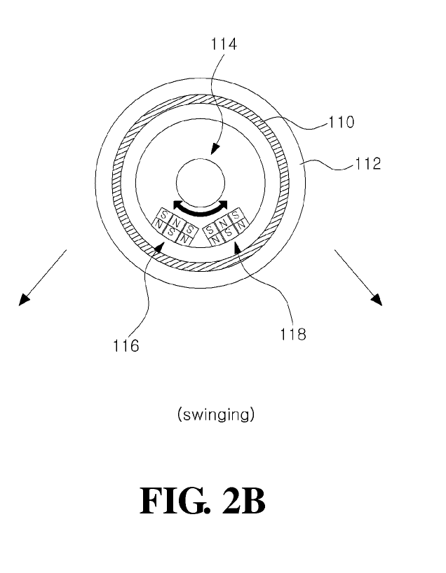

FIG. 1A and FIG. 1B are cross-sectional views schematically illustrating a sputtering apparatus according to a first disclosed embodiment of the invention, and FIG. 2A and FIG. 2B are diagrams illustrating the operation of a targeting module according to an embodiment of the invention.

Referring to FIG. 1A, a sputtering apparatus based on this embodiment may be an apparatus used for a deposition process, etc., and may include a chamber body 100, a target object holder 102, a targeting module 106, and a power supply part 120. Of course, the chamber may additionally include a gas inlet, a substrate entrance, a gas exhaust, etc., but the structure associated with these elements is well known in the art and as such will not be described here.

The target object holder 102 may be positioned inside the chamber body 100, for example on a bottom surface of the inside, and may serve to support a target object 104. The target object 104 is not limited to a particular type, as long as it is an object for which a deposition process is required, such as a semiconductor substrate, a board for a display component, a communication device, etc. According to an embodiment of the invention, the target object holder 102 can receive power from the power supply part 120 to function as an anode.

The targeting module 106 may be a module that includes a source 112, i.e. the material to be deposited, and can function as a cathode. Also, the targeting module 106 can additionally include a backing plate 110 and a magnet part 114. Such a targeting module 106 may have a generally cylindrical shape, but in FIG. 1A, a cross-sectional illustration is presented.

The backing plate 110 may be made of metal, for example, and can serve to support the source 112. Preferably, the backing plate 110 can be shaped as a circle, an ellipse, etc. The backing plate 110 may be supplied with power either directly or indirectly from the power supply part 120, and as a result, the backing plate 110 may serve as a cathode.

The source 112 may be made of a material (source material) that is to be deposited onto the target object 104, and may be shaped as a circle, etc., to be formed on the perimeter of the backing plate 110. According to an embodiment of the invention, the source 112 can rotate, as illustrated in FIG. 1A. Of course, the source 112 can itself be made to rotate or can be coupled to another member to rotate according to the rotation of the other member. That is, the structure for rotating the source 112 is not limited in a particular way as long as the source 112 is rotated.

The magnet part 114 can include a first magnet unit 116 and a second magnet unit 118, as illustrated in FIG. 1B.

The magnet units 116 and 118 can be positioned on an opposite side of the source 112 with respect to the backing plate 110, can be arranged symmetrically with respect to the center of the magnet part 114, and can have the same structure and poles, such as NSN, for example. Here, the magnet units 116 and 118 may include permanent magnets or electromagnets. Thus, the magnet units 116 and 118 may generate a magnetic field, and as a result, ions may be concentrated in region of the magnetic field via glow discharge. According to an embodiment of the invention, the magnet units 116 and 118 can be made to swing within a predefined range, as represented by the arrow in FIG. 1A, and can be arranged to face the target object holder 102.

Below, a description is provided of a procedure for depositing onto the target object 104 by using a sputtering apparatus according to an embodiment of the invention.

First, the target object 104 may be carried inside the chamber body 100 and placed on the target object holder 102.

Then, the inside of the chamber body 100 may change to a vacuum state, at which a sputtering gas, such as the inert gas argon (Ar), may be injected inside the chamber body 100.

Continuing on, the sputtering gas may be ionized, i.e. changed into a plasma state, due to the glow discharge caused by a potential difference between the cathode and anode.

The ions generated by the ionization may collide with the surface of the source 112, and the source material separated from the source 112 as a result may be deposited on the target object 104. In particular, due to the magnetic field generated by the magnet units 116 and 118, the ions may collide with the source 112 while concentrated in the region between the targeting module 106 and the target object 104, and thus the portion of the source 112 facing the target object 104 may be sputtered. The process of the ions colliding with the source 112 to generate the source material will hereinafter be referred to as a sputtering process.

According to an embodiment of the invention, the sputtering apparatus may rotate the source 112, as illustrated in FIG. 1A, so that the source 112 may be evenly sputtered. For example, the sputtering apparatus can rotate the source 112 by rotating the backing plate 110. Consequently, the entire source 112 may be sputtered evenly through the duration of the deposition process, and as a result, the lifespan of the source 112 can be lengthened. Lengthening the lifespan of the source 112 can also reduce the cost of the sputtering apparatus.

While the source 112 is being rotated, the magnet units 116 and 118 can be made to swing, as illustrated in FIG. 1A and FIG. 2B. As illustrated in FIG. 2A and FIG. 2B, the plasma region obtained when the magnet units 116 and 118 are swinging may be larger than the plasma region obtained when the magnet units 116 and 118 are stationary and not swinging. Consequently, the incident angle of the source material can be widened. Also, as the incident angle of the source material is not fixed, the deviations in deposition thickness on the target object 104 can be reduced.

That is, in the targeting module 106, the source 112 may be rotated, and the magnet units 116 and 118 may be swung.

Then, when the deposition process is completed, the vacuum inside the chamber body 100 may be relieved, and the target object 104 may be carried out through an exit.

In short, the sputtering apparatus according to an embodiment of the invention may use a cylindrically shaped targeting module 106, and during the deposition process, the source 112 of the targeting module 106 can be made to rotate, while the magnet units 116 and 118 can be made to swing. Thus, compared to the conventional sputtering apparatus in which the source is stationary, the sputtering apparatus based on an embodiment of the invention can lengthen the lifespan of the source 112 to reduce the cost of the sputtering apparatus, and can reduce deposition thickness deviations on the target object 104.

Although FIG. 1A does not illustrate the internal composition of the targeting module 106, the internal structure of the targeting module 106 can take various forms, as long as the source 112 is rotated, the magnet units 116 and 118 are swung, and the targeting module 106 acts as a cathode.

According to another embodiment of the invention, the magnetic field region generated by the magnet units 116 and 118 during the sputtering process or deposition process can be varied once or more. That is, the direction in which the magnetic field is outputted can be varied. Preferably, the sputtering apparatus may vary the magnetic field region by swinging the magnet units 116 and 118, but this does not mean that structures for varying the magnetic field region without swinging the magnet units 116 and 118 are excluded from the invention. That is, the structure of the targeting module 106 can be changed in various ways as long as the sputtering apparatus can vary the magnetic field region once or more during the sputtering process or deposition process.

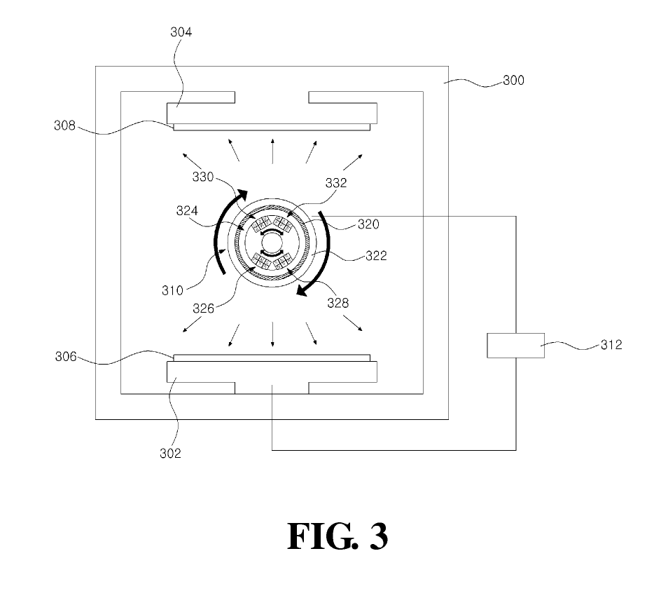

FIG. 3 is a cross-sectional view schematically illustrating a sputtering apparatus according to a second disclosed embodiment of the invention.

Referring to FIG. 3, a sputtering apparatus based on this embodiment may include a chamber body 300, a first target object holder 302, a second target object holder 304, a targeting module 310, and a power supply part 312.

Unlike the first disclosed embodiment, the sputtering apparatus of this embodiment may deposit the source material over two target objects 306 and 308.

The first target object holder 302 can be formed on a bottom portion of the inside of the chamber body 300, while the second target object holder 304 can be formed on an upper surface inside the chamber body 300. The target object holders 302 and 304 can be supplied with specified amounts of power from the power supply part 312.

The targeting module 310 may include a backing plate 320, a source 322, and a magnet part 324.

The magnet part 324 may include four magnet units 326, 328, 330, and 332 having identical structures. The magnet units 326 and 328 may be arranged symmetrically to each other with respect to the central axis, and may face the first target object holder 302. The magnet units 330 and 332 may be arranged symmetrically to each other with respect to the central axis, and may face the second target object holder 304. The magnet units 326 and 328 may generate a magnetic field to concentrate ions in a space corresponding to the first target object holder 302, and the magnet units 330 and 332 may generate a magnetic field to concentrate ions in a space corresponding to the second target object holder 304.

According to an embodiment of the invention, the source 322 may rotate, and the magnet units 326, 328, 330, and 332 may swing within a predefined range. More specifically, when the magnet units 326 and 328 move in a counterclockwise direction, the magnet units 330 and 332 may move in a clockwise direction, and when the magnet units 326 and 328 move in a clockwise direction, the magnet units 330 and 332 may move in a counterclockwise direction.

In short, the sputtering apparatus of this embodiment can use one targeting module 310 to deposit the source material on target objects 306 and 308 located at the top and bottom.

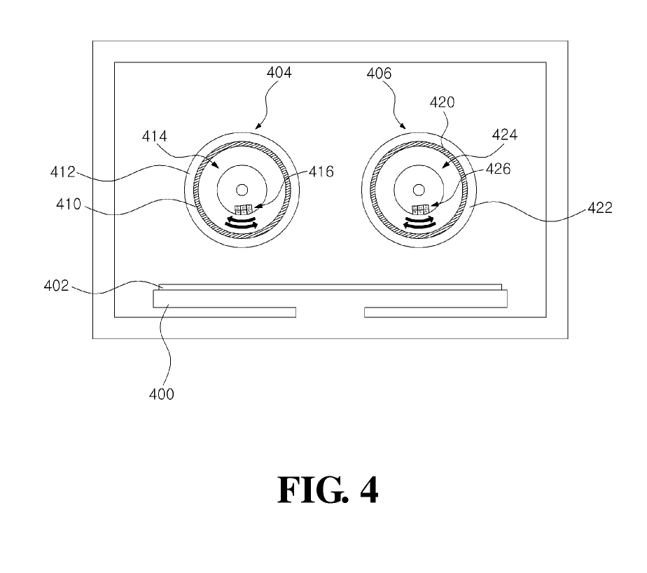

FIG. 4 is a cross-sectional view schematically illustrating a sputtering apparatus according to a third disclosed embodiment of the invention.

Referring to FIG. 4, a sputtering apparatus based on this embodiment can include two targeting modules 404 and 406.

The targeting modules 404 and 406 can have the same structure and can be arranged in parallel over the target object holder 400 and the target object 402.

A first targeting module 404 may include a first backing plate 410, first source 412, and first magnet part 414, while a second targeting module 406 may include a second backing plate 420, second source 422, and second magnet part 424.

The first magnet part 414 may have at least one magnet unit 416, and the second magnet part 424 can include one or more magnet unit 426. The magnet units 416 and 426 may each be made to swing. According to an embodiment of the invention, the magnet units 416 and 426 can swing in opposite directions. For example, when the magnet unit 416 moves in a clockwise direction, the magnet unit 426 can move in a counterclockwise direction.

According to another embodiment of the invention, each of the magnet parts 414 and 416 can include multiple magnet units, for example two magnet units, where one of the two magnet units can be positioned in correspondence to a first target object holder and the other magnet unit can be positioned in correspondence to a second target object holder.

In short, the sputtering apparatus of this embodiment can include a multiple number of targeting modules, and each targeting module can have at least one magnet unit.

The embodiments of the invention described above are disclosed for illustrative purposes. Those of ordinary skill in the field of art to which the present invention pertains would understand that various modifications, alterations, and additions can be made without departing from the spirit and scope of the invention, and that such modifications, alterations, and additions are encompassed by the scope of claims below.

What is claimed is:

1. A sputtering apparatus comprising:
a chamber body; and
a targeting module positioned inside the chamber body, the targeting module having a source and at least one magnet unit, the magnet unit configured to generate a magnetic field,
wherein the magnet unit swings during a sputtering process.

2. The sputtering apparatus of claim 1, wherein the targeting module further comprises a backing plate,
the source is formed on a perimeter of the backing plate, and the magnet unit is positioned on an opposite side of the source with respect to the backing plate.

3. The sputtering apparatus of claim 2, further comprising:
a target object holder configured to support a target object; and
a power supply part configured to supply power to the target object holder and the backing plate,
wherein the magnet unit is arranged to face the target object holder, and the backing plate and the target object holder function respectively as a cathode and an anode.

4. The sputtering apparatus of claim 1, wherein the target module comprises two magnet units, and
the magnet units have an identical structure and are arranged symmetrically with respect to a central axis of the targeting module.

5. The sputtering apparatus of claim 1, wherein the source is rotated during the sputtering process.

6. A targeting module used in a sputtering apparatus, the targeting module comprising:
a source; and
a magnet part having at least one magnet unit configured to generate a magnetic field,
wherein the magnet part is capable of swinging.

7. The targeting module of claim 6, further comprising a backing plate,
wherein the source is formed on a perimeter of the backing plate, and the magnet part is positioned on an opposite side of the source with respect to the backing plate.

8. The targeting module of claim 6, wherein the magnet part comprises two magnet units, and
the magnet units have an identical structure and are arranged symmetrically with respect to a central axis of the targeting module.

9. The targeting module of claim 6, wherein the source is rotated during a sputtering process.

10. A sputtering process comprising:
generating ions;
concentrating the ions by generating a magnetic field; and
sputtering a source with the ions,
wherein an output direction of the magnetic field is changed once or more during the sputtering.

11. The sputtering process of claim 10, wherein a magnet unit for generating the magnetic field faces a direction of a target object and swings within a predefined angle range.

12. The sputtering process of claim 10, wherein the source is continuously rotated during the sputtering.
